(19) United States
(12) Patent Application Publication
(10) Pub. No.: US 2022/0186356 A1
(43) Pub. Date: Jun. 16, 2022

(54) Laser-Based Method and System for Marking a Workpiece

(71) Applicant: JVIS-USA, LLC, Sterling Heights, MI (US)

(72) Inventors: Shawn Murray, Oxford, MI (US); Darius J. Preisler, Macomb, MI (US); David R. Syrowik, Novi, MI (US)

(73) Assignee: JVIS-USA, LLC, Sterling Heights, MI (US)

(21) Appl. No.: 17/685,920

(22) Filed: Mar. 3, 2022

Related U.S. Application Data
(62) Division of application No. 16/814,435, filed on Mar. 10, 2020.

(51) Int. Cl. C23C 8/60; C23C 8/02

(52) U.S. Cl. CPC C23C 8/60; H01L 21/67282; C23C 8/02

(57) ABSTRACT

A method and system for marking a workpiece at a marking location by infusing colorant into targeted surface material within a region of the workpiece via laser-induced chemical etching are disclosed. The system includes a laser subsystem for generating a pulsed laser output and a transport subsystem including a medium containing the colorant mounted immediately adjacent the marking location to transfer the colorant to the targeted surface material upon impact by the pulsed laser output. The system also includes a delivery subsystem for irradiating the medium and the targeted surface material with the pulsed laser output to melt the targeted surface material to obtain molten material and to transfer the colorant from the medium to the molten material. The molten material allows the transferred colorant to thermally diffuse into and chemically bond to the molten material. Each laser pulse creates a microtextured colorized spot of material on the workpiece.

### CROSS-REFERENCE TO RELATED APPLICATIONS

This application is a divisional of U.S. application Ser. No. 16/814,435 filed Mar. 10, 2020, the disclosure of which is hereby incorporated in its entirety by reference herein.

### TECHNICAL FIELD

At least one embodiment of the present invention generally relates to laser-based methods and systems for marking workpieces and, in particular, to such methods and systems which utilize laser-induced chemical etching.

### Overview

Labelling ferrous and non-ferrous metals for identification or decoration is oftentimes accomplished via painting, silkscreens, adhesive decals, etc. New templates need to be created for each different serial number. Other deficiencies of such prior art methods include rubbing off, accuracy of location and clarity of design.

A laser is a device that emits a beam of coherent light through an optical amplification process. There are many types of lasers including gas lasers, fiber lasers, solid-state lasers, dye lasers, diode lasers, and excimer lasers.

As described in Chapter 15 of the “Handbook of Laser Materials Processing,” using a laser to mark or code information on a product-laser marking—is one of the most common industrial applications of lasers. Laser marking often takes the form of an alphanumeric code imprinted on the label or on the surface of the product to describe date of manufacture, best-before date, serial number of part number, but the mark can also be a machine-readable bar code or 2D symbol (ID matrix). As well as coding, laser marking sometimes takes the form of functional marking (such as gradation lines on a syringe) or decorative marking (such as a logo or graphic image on an integrated circuit). Laser marking is often one of the final processes in the assembly of a product, taking place during the final filling cycle at a brewery, for example, or on a finished product before it is boxed for shipment. Compared to other on-line marking techniques, such as inkjet, hot stamping, or mechanical scribing, laser marking offers may advantages: indelibility, reliability, no consumables, cleanliness and high speed. Laser marking is usually the best marking solution with one proviso: Not all materials mark well with every laser.

Laser marking can take a number of forms: 1. black carbonization, 2. Bleaching or changing the color of the material, 3. physical modification of the surface finish, 4. scribing a shallow groove into the material by vaporization, 5. controlled modification of the surface by melting, or 6. A combination of any of the above. In some cases, a surface mark by color change with little material removal is desired. On the other hand, noncolored marks that scribe a shallow groove into the material are sometimes desired to provide resistance to abrasion.

Laser marking is a surface process. Typically, the light absorbed during the optical pulse (which can be very short, e.g., <0.1 μs) is transformed into heat, thereby creating a high “instantaneous” temperature rise in the material, resulting in surface melting and resolidification, carbonization, chemical decomposition, or explosive ejection of the material. The resultant mark consists typically of a crater of shallow depth, surface modification within the crater and around the heat-affected zone, a raised ridge or kerf around the crater, and debris scatters nearby.

FIG. 1 is a schematic representation of a prior art laser-marked surface. A kerf may be present only for cases where melting and material flow has occurred. Depending on the laser and beam delivery process used, the depth of the crater can be negligible or as much as 0.005 in. Although subsurface marking is possible on some materials, it is not a common application.

CO₂ lasers are used to engrave items to depth and to surface engrave. Items made of nonmetals such as wood, plastic, leather, or rubber absorb the 10.6 μm wavelength of the CO₂ laser very well. They have a low enough vaporization temperature that the vapors can be removed from the cut area easily. It is easy to engrave a deep image into these materials.

Surface engraving with a CO₂ laser typically involves removing a thin surface coating applied to a different type of substrate. This may be paint on a metal surface or a thin plastic coating on a plastic or metal substrate. Surfaces engaging also can be accomplished on a solid material by changing the surface color or texture but not engraving to any significant depth.

Engraving into metal is not a strong point of the CO₂ laser because the 10.6 μm wavelength does not couple well into the surface of metals. Ferrous metal such as stainless steel can be effectively marked with higher-power CO₂ lasers, however.

Nd:YAG lasers are good for surface engraving many types of materials. The 1.06 μm wavelength couples much more effectively into metals than the CO₂ wavelength and is typically the laser choice for metal engraving.

The CO₂ laser will not couple into metals well but can be used for removing a coating from metals, which will provide a form of engraving.

Excimer laser marking systems are typically more complex than those used with CO₂ or Nd:YAG lasers, so their use is preferred in applications where they offer a distinct functional advantage. The most important advantages are related to the color change marking approach (without any material removal) and the sub-micrometer ablation precision for engraving. The various methods or techniques of marking possible using excimer lasers are listed in the table of FIG. 2, along with the benefits of each.

Recrystallization may occur during or after deformation (during cooling or a subsequent heat treatment, for example). The former is termed dynamic while the latter is termed static. In addition, recrystallization may occur in a discontinuous manner, where distinct new grains form and grow, or a continuous manner, where the microstructure gradually evolves into a recrystallized microstructure.

The term phase transition (or phase change) is most commonly used to describe transitions between solid, liquid, and gaseous states of matter. A phase of a thermodynamic system and the states of matter have uniform physical properties. During a phase transition of a given medium, certain properties of the medium change, often discontinuously, as a result of the change of external conditions, such as temperature, pressure or others.

Although very similar in some respects, the technological aspects of etching vs engraving also share many bold dissimilarities. Etching and engraving are both methods of cutting lines into a hard surface, such as metal. The primary difference between them is that engraving is a physical process and etching is a chemical process.

For example, laser engraving cuts a cavity through the material's surface leaving a cavity that reveals an image or writing at eye level that is noticeable to the touch as well. Laser etching on the other hand basically sweeps away a top layer of material without cutting into the metal and creating a crevice. Laser engraving is accomplished by using a high heat laser that causes the material surface to vaporize. In contrast, laser etching machines are less powerful and provide only a fraction of the cutting capabilities of a laser engraver.

Some of the more important features of engraving, include:
The laser creates high heat during the engraving process, which essentially causes the material to vaporize.
It's a quick process, as the material is vaporized with each pulse.
This creates a cavity in the surface that is noticeable to the eye and touch.
To form deeper marks with the laser engraver, repeat with several passes.
Provides durability, speed, cost efficiency & ultimate repeatability.

Engraving depth can vary between 0.02″ in metals to 0.125″ in harder materials. One can engrave almost any type of material but is most commonly used for metal, plastics, wood, leather, glass and acrylic.

Etching shares many similarities with engraving, of which the aim is to produce crevices and lines below the surface of the material. Laser etching occurs when the heat from the beam causes the surface of the material to melt. The melted material expands and causes a raised mark. Such raised marks change the surface finish of metals thereby altering the metals' reflectivity and enhancing contrast. The depth of a laser etch may be 0.0001 inches and is usually no more than 0.001″. The numerous advantages of etching include:
Extremely precise
Material savings
High speed of realization
Available for numerous materials
Provides durability, speed, cost efficiency & ultimate repeatability

Discrete areas of laser-patterned microtextured material may be used to create high contrast marking on metals such as titanium or steel. Nearly periodic and sharp variation in roughness may be produced with femtosecond laser pulses. Spikes of “spikey” textured regions may have a height ranging from a fraction of one micron to tens of microns. The surface profile may be strongly dependent on laser parameters including pulse duration (i.e., width), peak energy, spot diameter, and spot irradiance profile. Such spike formation may involve both laser ablation and laser-induced chemical etching, wherein laser stimulated chemical reactions occur at laser fluences/powers that are substantially below those required for structuring by direct ablation.

U.S. patents assigned to Micron Technology Inc. disclose a laser marking apparatus and method for marking the surface of a semiconductor chip. A laser beam is directed to a location on the surface of the chip where a laser reactive material, such as a pigment containing epoxy, is present. The heat associated with the laser beam causes the laser reactive material to fuse to the surface of the chip creating a visibly distinct mark in contrast to the rest of the surface of the chip. Only reactive material contacted by the laser fuses to the chip surface, and the remaining residue on the non-irradiated portion is removed. These patents include: U.S. Pat. Nos. 5,838,361; 5,985,377; 6,108,026; 6,113,992; 6,217,949; 6,342,912; 6,429,890; 6,683,637; and 7,452,732.

U.S. Pat. No. 7,209,884 discloses a laser marking system for automotive glass having an ink spray device capable of depositing an ink layer upon the glass and a drying system for accelerating the drying of the ink layer. A laser system is also provided to operably heat and bond at least a portion of the ink layer to the glass in a predetermined pattern. A cleansing system removes unbonded portions of the ink layer from the glass and a controller is provided to direct the laser system in the predetermined pattern.

Despite the above, there is still a need for an improved laser-based method and system for marking workpieces for decoration and/or identification.

### SUMMARY

An object of at least one embodiment of the present invention is to provide a laser-based method and system for marking workpieces with colorized marks which are durable, progressive and programmable.

In carrying out the above object and other objects of at least one embodiment of the present invention, a method of marking a workpiece by infusing colorant into targeted surface material within a region of the workpiece via laser-induced chemical etching is provided. The method includes the steps of providing a transport subsystem including a medium containing the colorant immediately adjacent the region of the workpiece to be marked, generating a pulsed laser output having a plurality of laser pulses and irradiating the medium and the targeted surface material in the region with the pulsed laser output to melt the targeted surface material to obtain molten material and to transfer the colorant from the medium to the molten material. The molten material allows the transferred colorant to thermally diffuse into and chemically bond to the molten material. The method also includes allowing the molten material and the colorant infused into the molten material to solidify wherein each laser pulse creates a microtextured colorized spot of material on the workpiece.

The colorant may be an ink.

The medium may be a ribbon of ink-bearing material.

The subsystem may include a pair of spaced reels including a drive reel and an actuator assembly for rotatably driving the drive reel to advance the medium.

The targeted surface material may be a metal layer.

The workpiece may be a metal plate.

Further in carrying out the above object and other objects of at least one embodiment of the present invention, a system for marking a workpiece at a marking location by infusing colorant into targeted surface material within a region of the workpiece via laser-induced chemical etching is provided. The system includes a laser subsystem for generating a pulsed laser output having a plurality of laser pulses and a transport subsystem including a medium containing the colorant mounted immediately adjacent the marking location to transfer the colorant from the medium to the targeted surface material of the workpiece upon impact by the pulsed laser output. The system also includes a delivery subsystem for irradiating the medium and the targeted surface material in the region with the pulsed laser output to melt the targeted surface material to obtain molten material and to transfer the colorant from the medium to the molten material. The molten material allows the transferred colorant to thermally diffuse into and chemically bond to the molten material. Each laser pulse creates a microtextured colorized spot of material on the workpiece.

The colorant may be an ink.

The medium may be a ribbon of ink-bearing material.

The transport subsystem may include a pair of spaced reels including a drive reel and an actuator assembly for rotatably driving the drive reel to advance the medium.

The targeted surface material may be a metal layer.

The workpiece may be a metal plate.

### BRIEF DESCRIPTION OF THE DRAWINGS

FIG. 1 is a side, schematic view of a prior art laser-marked surface;

FIG. 2 is a table showing various marking mechanisms and methods using an excimer laser;

FIGS. 3 and 4 are schematics illustrating, by way of example, a mark is the form of a microtextured colorized spot formed on a specular metal surface using at least one embodiment of the present invention;

FIG. 5 is a schematic block diagram showing some of the elements of a laser-based marking system constructed in accordance with at least one embodiment of the present invention; and

FIG. 6 shows graphs of temperature versus depth into metal which illustrates the effect of thermal diffusion with a 10 nanosecond laser pulse.

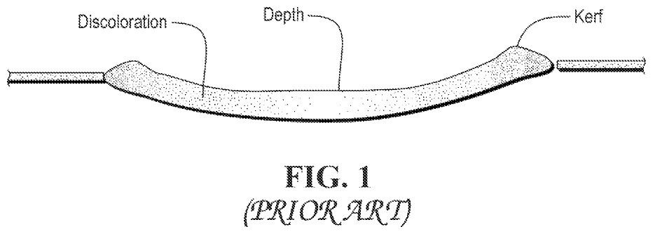

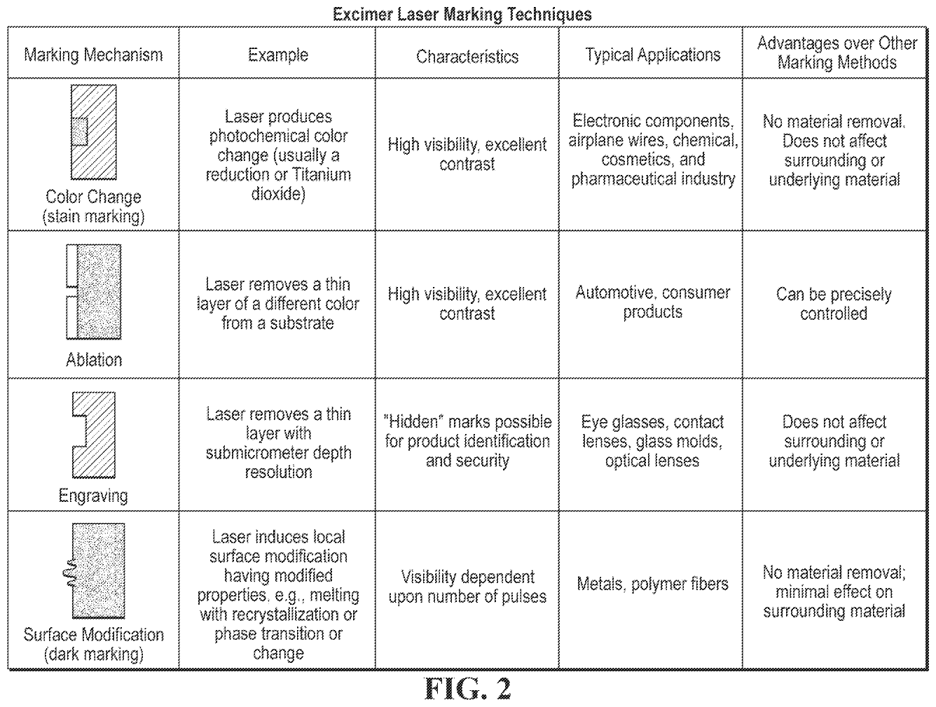

### DETAILED DESCRIPTION OF AT LEAST ONE EMBODIMENT OF THE PRESENT INVENTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

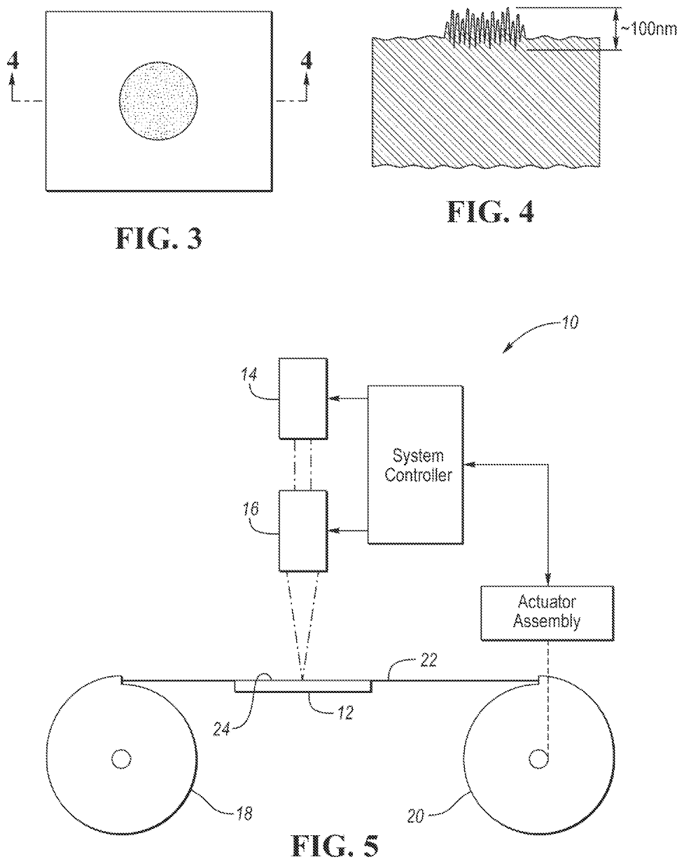

Turning to FIG. 5, there is illustrated a representation of a general embodiment of a laser marking system, generally indicated at 10, for marking via etching, a metal workpiece 12 using a focused pulsed laser beam generated by a laser subsystem including a laser 14, such as Q-switched pulsed laser. The pulsed laser beam not only liquefies or melts a spot of material (i.e., FIG. 3) on the workpiece 12 but also transfers a colorant such as ink to the molten material. After solidification, a microtextured colorized spot of material remains on the workpiece 12.

A clear advantage of using the pulsed laser 14 versus using CW laser with modulation lies in the total average laser power needed for the process. For example, for a dose 0.1 μj with 20-ns pulse duration, it requires a 5-watt CW laser. For the same dose at 50 KHz, it requires only a 5-mw pulsed laser, a reduction of 1,000 times in average power. A milli-watt level laser can easily be air-cooled while a multi-watt laser may have to be water-cooled. The footprint of a milli-watt level laser is also much smaller than that of a multi-watt level laser.

U.S. Patent Document No. 2006/0000814 is hereby incorporated by reference in its entirety herein especially for its discussion of the various laser subsystems and delivery subsystems for use in the laser-based marking system constructed in accordance with at least one embodiment of the present invention. FIGS. 12 and 13 of the above-noted patent document are reproduced herein as drawing FIGS. 3 and 4. FIGS. 3 and 4 are schematics illustrating, by way of example, a colorized mark formed on the specular surface 24 of the workpiece 12 using a system of the present invention. The pulsed laser 14 may be picosecond laser producing a pulsed output with total energy density (in one or more pulses) sufficient to initiate ablation within a portion of a spot area on the workpiece surface 24. The resulting microtextured surface has surface height variations from tens to hundreds of nanometers. The marked region generally shows significant roughness and eliminates at least strong reflection components.

Contributing to the marking process are at least the following parameters: laser beam spot size, laser beam profile, location of the laser beam on the marking area (and its accuracy), number of the laser pulses, laser pulse energy, laser pulse width and laser pulse shape (temporal profile).

The workpiece 12 may be placed on a positioning table or X-Y stage and may be subjected to an application of a focused laser pulse which is produced by the laser 14. The laser pulses are directed to and focused on the workpiece 12 by using a delivery subsystem in the form of a machining head and/or objective lens 16. Alternatively, the table or stage may be stationary and the head or lens 16 may move in two or three dimensions.

The marking system 10 generally includes the laser subsystem, the delivery subsystem, and an ink tape or transport subsystem, which cooperate and are coordinated to operate together via a system controller to permanently apply colorized indicium or marks upon the workpiece 12. The laser subsystem, as described above, is provided for heating selected portions of a colorant such as ink via laser pulses in a predetermined pattern to help create the indium by transforming ink to the workpiece 12. In the present embodiment, ink is provided via the ink tape subsystem. The ink tape subsystem includes a pair of reels 18 and 20 disposed on opposite sides of the laser 14. A first reel 18 of the pair of reels 18 and 20 is adapted to carry unused ink tape 22 and the other reel 20 of the pair of reels 18 and 20 is adapted to carry used ink tape 22. The ink tape 22 spans across and is immediately adjacent the upper surface 24 of the metal workpiece 12 adjacent an area to be marked. The ink tape 22 may be held in this position adjacent the area to be marked using a retaining member (not shown). Ideally, the retaining member is held in contact with ink tape 22 to hold the ink tape 22 generally flat and in contact with the surface 24 of the workpiece 12.

The reel 20 is a drive reel 20 of the tape subsystem and is driven by an actuator or rotary motor assembly under control of the system controller to rotatably drive the drive reel 20 to advance the tape 22.

The laser 14 is actuated under control of the system controller to heat selected portions of the ink tape 22 which causes those exposed portions of ink tape 22 to deposit or transfer the ink onto the molten metal of the workpiece 12 after it too is irradiated with the laser beam pulse. The laser beam is only directed to those portions of the ink tape 22 whose ink is to be infused or diffused into the molten metal. It should be appreciated that the system controller, the laser 14 and the delivery system are capable of creating any one of an infinite number of designs, which may include names, logos, serial numbers, bar codes, data matrices, and the like. As each indicium is formed, used ink tape may be advanced, either manually or automatically, via the actuator assembly to provide a “fresh” portion of unused ink tape.

Heat Affected Zone (HAZ) is a three Dimensional Effect

When a laser pulse hits a spot on the metal workpiece 12, the electrons in the workpiece 12 absorb the laser energy very quickly (less than pico seconds). The energy is then transferred to the area surrounding the spot via electron-lattice interaction, generally called “thermal diffusion.”

This diffusion effect is three dimensional, i.e., the energy will transfer in all directions (not only in the lateral x and y plane, but in the z direction as well). The dimension z of the thermal diffusion can be estimated by the square root of the product of pulse width, tₚ, and material diffusivity, D.

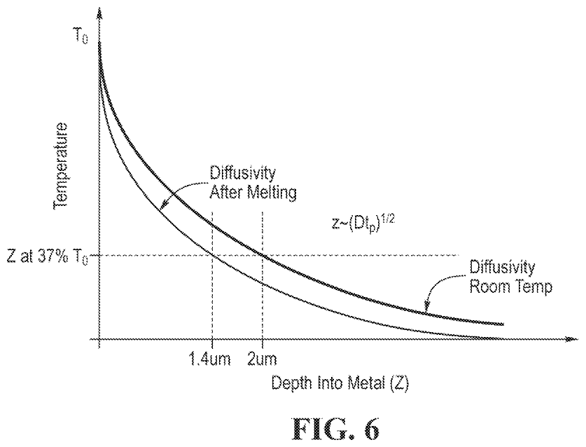

The curves of FIG. 6 illustrates the effect of thermal diffusion with a 10 nano-second laser pulse interacting with copper and aluminum (they both have similar thermal diffusivity).

Thermal diffusivity of selected metals and other materials are given by the following table:

| | Thermal | Thermal |
|---|---|---|
| | diffusivity | diffusivity |
| Material | (m²/s) | (mm²/s) |
| Pyrolytic graphite, parallel to layers | 1.22 × 10⁻³ | 1220 |
| Silver, pure (99.9%) | 1.6563 × 10⁻⁴ | 165.63 |
| Gold | 1.27 × 10⁻⁴ | 127 |
| Copper at 25° C. | 1.11 10⁻⁴ | 111 |
| Aluminum | 9.7 × 10⁻⁵ | 97 |
| Al—10Si—Mn—Mg (Silafont 36) at | 74.2 × 10⁻⁶ | 74.2 |
| 20° C. | | |
| Aluminum 6061-T6 Alloy | 6.4 × 10⁻⁵ | 64 |
| Al—5Mg—2Si—Mn (Magsimal-59) at | 4.4 × 10⁻⁵ | 44.0 |
| 20° C. | | |
| Steel, AISI 1010 (0.1% carbon) | 1.88 × 10⁻⁵ | 18.8 |
| Steel, 1% carbon | 1.172 × 10⁻⁵ | 11.72 |
| Steel, stainless 304A at 27° C. | 4.2 × 10⁻⁶ | 4.2 |
| Steel, stainless 310 at 25° | 3.352 × 10⁻⁶ | 3.352 |
| Inconel 600 at 25° C. | 3.428 × 10⁻⁶ | 3.428 |
| Molybdenum (99.95%) at 25° C. | 54.3 × 10⁻⁶ | 54.3 |
| Iron | 2.3 × 10⁻⁵ | 23 |

In at least one embodiment of the present invention, a method of iteratively, selectively and accurately marking by etching with a colorant such as ink is done by diffusion of colorant. The method includes: directing a focused pulsed laser source to a selected area of the ink tape and the workpiece to irradiate them, and applying a laser pulse from the focused pulsed laser source thereto. The laser pulse melts the selected area thereby allowing the diffusion or infusion of colorant into and chemically bond to the molten material. The method also includes allowing the melted selected area to solidify. Each laser pulse creates a microtextured colorized spot of material (i.e., FIGS. 3 and 4) on the workpiece 12.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1-6. (canceled)

7. A system for marking a workpiece at a marking location by infusing colorant into targeted surface material within a region of the workpiece via laser-induced chemical etching, the system comprising:
a laser subsystem for generating a pulsed laser output having a plurality of laser pulses;
a transport subsystem including a medium containing the colorant mounted immediately adjacent the marking location to transfer the colorant from the medium to the targeted surface material of the workpiece upon impact by the pulsed laser output; and
a delivery subsystem for irradiating the medium and the targeted surface material in the region with the pulsed laser output to melt the targeted surface material to obtain molten material and to transfer the colorant from the medium to the molten material in a predetermined pattern, the molten material allowing the transferred colorant to thermally diffuse into and chemically bond to the molten material wherein each laser pulse creates a microtextured colorized spot of material on the workpiece and wherein the microtextured colorized spots of material create a marked region of the workpiece.

8. The system as claimed in claim 7, wherein the colorant is an ink.

9. The system as claimed in claim 8, wherein the medium is a ribbon of ink-bearing material.

10. The system as claimed in claim 7, wherein the transport subsystem includes a pair of spaced reels including a drive reel and an actuator assembly for rotatably driving the drive reel to advance the medium.

11. The system as claimed in claim 7, wherein the targeted surface material is a metal layer.

12. The system as claimed in claim 7, wherein the workpiece is a metal plate.

13. A system for marking a workpiece having a specular metal surface at a marking location by infusing colorant into targeted surface material within a region of the workpiece via laser-induced chemical etching, the system comprising:
a laser subsystem for generating a pulsed laser output having a plurality of laser pulses;
a transport subsystem including a medium containing the colorant mounted immediately adjacent the marking location to transfer the colorant from the medium to the targeted surface material of the workpiece upon impact by the pulsed laser output; and
a delivery subsystem for irradiating the medium and the targeted surface material in the region with the pulsed laser output to melt the targeted surface material to obtain molten material and to transfer the colorant from the medium to the molten material in a predetermined pattern, the molten material allowing the transferred colorant to thermally diffuse into and chemically bond to the molten material wherein each laser pulse creates a microtextured colorized spot of material on the specular metal surface of the workpiece and wherein the microtextured colorized spots create a marked region which shows significant roughness and eliminates at least strong reflection components.

14. The system as claimed in claim 13, wherein the colorant is an ink.

15. The system as claimed in claim 14, wherein the medium is a ribbon of ink-bearing material.

16. The system as claimed in claim 13, wherein the transport subsystem includes a pair of spaced reels including a drive reel and an actuator assembly for rotatably driving the drive reel to advance the medium.

17. The system as claimed in claim 13, wherein the targeted surface material is a metal layer.

18. The system as claimed in claim 13, wherein the workpiece is a metal plate.

19. A system for marking a workpiece at a marking location by infusing colorant into targeted surface material having a thermal diffusivity within a region of the workpiece via laser-induced chemical etching, the system comprising:
a laser subsystem for generating a pulsed laser output having a plurality of laser pulses, each of the pulses having a pulse width;
a transport subsystem including a medium containing the colorant mounted immediately adjacent the marking location to transfer the colorant from the medium to the targeted surface material of the workpiece upon impact by the pulsed laser output; and
a delivery subsystem for irradiating the medium and the targeted surface material in the region with the pulsed laser output to melt the targeted surface material to obtain molten material and to transfer the colorant from the medium to the molten material, the molten material allowing the transferred colorant to thermally diffuse into and chemically bond to the molten material wherein each laser pulse creates a microtextured colorized spot of material on the workpiece and wherein the microtextured colorized spots of material create a marked region of the workpiece and wherein energy from the laser pulses is transferred to the area around each of the spots via thermal diffusion and wherein the thermal diffusion is based on the pulse width of the pulses and the thermal diffusivity of the surface material.

20. The system as claimed in claim 19, wherein the colorant is an ink.

21. The system as claimed in claim 20, wherein the medium is a ribbon of ink-bearing material.

22. The system as claimed in claim 19, wherein the transport subsystem includes a pair of spaced reels including a drive reel and an actuator assembly for rotatably driving the drive reel to advance the medium.

23. The system as claimed in claim 19, wherein the targeted surface material is a metal layer.

24. The system as claimed in claim 19, wherein the workpiece is a metal plate.
